(19) United States
(12) Patent Application Publication
(10) Pub. No.: US 2012/0152309 A1
(43) Pub. Date: Jun. 21, 2012

(54) ALIGNMENT OF PHOTOVOLTAIC CELLS WITH RESPECT TO EACH OTHER DURING MANUFACTURING AND THEN MAINTAINING THIS ALIGNMENT IN THE FIELD

(75) Inventors: Wayne Miller, Los Altos, CA (US); Victor Ocegueda, Fremont, CA (US); Jeremy Dittmer, Palo Alto, CA (US); Roger Sinsheimer, Los Gatos, CA (US); Mike Prucha, Ben Lomond, CA (US)

(73) Assignee: GREENVOLTS, INC, FREMONT, CA (US)

(21) Appl. No.: 13/227,649

(22) Filed: Sep. 8, 2011

Related U.S. Application Data
(60) Provisional application No. 61/424,537, filed on Dec. 17, 2010.
(60) Provisional application No. 61/424,515, filed on Dec. 17, 2010.
(60) Provisional application No. 61/424,518, filed on Dec. 17, 2010.

(51) Int. Cl. H01L 31/052; H01L 31/18

(52) U.S. Cl. 136/246; 29/890.033

(57) ABSTRACT

Methods and apparatus are described for a concentrated photovoltaic system. A method of creating a paddle structure with a set of solar receivers that are aligned within and mechanically secured in place in each module contained in a paddle structure. Each solar receiver is assembled and aligned, where the assembly of the solar receiver establishes the alignment of the secondary optic to the photovoltaic solar cell. The assembly of a module with its set of solar receivers establishes the alignment in three dimensions the solar receivers with each other. Individual parts making up the receiver are 1) shaped, 2) sized, 3) keyed, 4) pinned and 5) any combination of these to fit together in only one way so that all of the solar receivers containing the photovoltaic solar cell maintain their alignment when installed in a given CPV module.

### RELATED APPLICATIONS

This application is a continuation in part of and claims the benefit of and priority to U.S. Provisional Application titled “Integrated electronics system” filed on Dec. 17, 2010 having application Ser. No. 61/424,537, U.S. Provisional Application titled “Two axis tracker and tracker calibration” filed on Dec. 17, 2010 having application Ser. No. 61/424,515, and U.S. Provisional Application titled “Photovoltaic cells and paddles” filed on Dec. 17, 2010 having application Ser. No. 61/424,518.

### FIELD

In general, a photovoltaic system having a two-axis tracker assembly for a photovoltaic system is discussed.

### BACKGROUND

A two-axis tracker may break up its solar array for more efficient operation. A two axis tracker may be designed for easier of installation in the field.

### SUMMARY

Various methods and apparatus are described for a photovoltaic system. In an embodiment, the solar array has multiple discreet components that at least include the following. A set of solar receivers that are aligned within and mechanically secured in place in each module contained in a paddle structure that makes up the solar array. Each solar receiver has its own secondary concentrator optic optically coupled to a photovoltaic cell. Each paddle structure is constructed such that one or modules with their set of solar receivers contained in the paddle structure maintain the set of solar receivers' alignment in three dimensions when installed in the paddle structure in the fabrication process and while installed in the field. The set of solar receivers are aligned in three dimensions with each other by the fabrication process of the module template and installation of the solar receivers into the module template. Individual parts making up the solar receiver are 1) shaped, 2) sized, 3) keyed, 4) pinned and 5) any combination of these to fit together in only one way so that all of the solar receivers in the set maintain their alignment when installed in a given module. Each paddle structure has a skeleton frame that couples to the one or more modules, which each module contains its own set of solar receivers arranged in a grid like pattern that are aligned in the three dimensions with each other during the fabrication process when installed in that module. A configuration and organization of the paddle structure maintains the three dimensional alignment of the installed modules during shipment as well as during an operation of the solar array. Each module is mechanically secured in place with a frame of the paddle structure.

### BRIEF DESCRIPTION OF THE DRAWINGS

The multiple drawings refer to the embodiments of the invention.

FIGS. 1A and 1B illustrate diagrams of an embodiment of a two axis tracking mechanism for a concentrated photovoltaic system having multiple independently movable sets of concentrated photovoltaic solar (CPV) cells.

FIG. 2 illustrates a diagram of an embodiment of the assembled solar receiver.

FIGS. 3a and 3b illustrate diagrams of an embodiment of an assembled and aligned solar receiver containing a concentrated photovoltaic cell.

FIGS. 4a and 4b illustrate diagrams of an embodiment of a Fresnel lens optically coupling to the solar receiver.

FIG. 5 illustrates a diagram of an embodiment of the solar receiver casing mating to a flat heat spreader inside the module and a heat sink extending outside the module.

FIG. 6 illustrates a diagram of an embodiment of the solar receiver attaching from the bottom to the chassis of the module.

FIGS. 7a and 7b illustrate diagrams of an embodiment of an initial step of the assembly of a module with multiple receivers set in place on a receiver to chassis fixture.

FIG. 8 illustrates a diagram of an embodiment of a module assembly created with a rectangular grid containing a set of, for example 24, individual concentrated photovoltaic cells each in its own solar receiver.

FIG. 9 illustrates a diagram of an embodiment of a chassis of a module.

FIG. 10 illustrates a diagram of an embodiment of a solar receiver having sets of precisely drilled holes in the heat spreader of the receiver that exactly correspond to holes in the chassis of the module template.

FIG. 11 illustrates an exploded view of a diagram of an embodiment of a module having installed a set of solar receivers, a patterned panel of Fresnel lenses, a vent cover and other features.

FIG. 12 illustrates a diagram of an embodiment of a module assembly with all the solar receivers wired together internally within the module.

FIG. 13 illustrates a top down perspective view of an embodiment of an assembled paddle structure.

FIG. 14 illustrates a bottom up perspective view of an embodiment of an assembled paddle structure.

FIG. 15 illustrates a top down perspective exploded view of an embodiment of an assembled paddle structure.

FIG. 16 illustrates a bottom up perspective exploded view of an embodiment of an assembled paddle structure.

FIG. 17 illustrates a diagram of an embodiment of double nutting across a bracket on the skeletal frame of the paddle structure to the threaded insert of the module.

FIG. 18 illustrates a diagram of an embodiment of a module assembly created with a vent cover on the exterior of the module.

While the invention is subject to various modifications and alternative forms, specific embodiments thereof have been shown by way of example in the drawings and will herein be described in detail. The invention should be understood to not be limited to the particular forms disclosed, but on the contrary, the intention is to cover all modifications, equivalents, and alternatives falling within the spirit and scope of the invention.

### DETAILED DISCUSSION

In the following description, numerous specific details are set forth, such as examples of specific cells, named components, connections, types of connections, etc., in order to provide a thorough understanding of the present invention. It will be apparent, however, to one skilled in the art that the present invention may be practiced without these specific details. In other instances, well known components or methods have not been described in detail but rather in a block diagram in order to avoid unnecessarily obscuring the present invention. Further specific numeric references such as a first paddle, may be made. However, the specific numeric reference should not be interpreted as a literal sequential order but rather interpreted that the first paddle is different than a second paddle. Thus, the specific details set forth are merely exemplary. The specific details may be varied from and still be contemplated to be within the spirit and scope of the present invention.

In general, various methods and apparatus are discussed for a photovoltaic system. An alignment of the PV cells with respect to each other occurs during the manufacturing process and then is maintained. In an embodiment, a method of creating a paddle structure with a set of solar receivers that are aligned within and mechanically secured in place in each module contained in a paddle structure. This process has many steps including: 1) assembly and alignment of a solar receiver; 2) assembly and alignment of a set of solar receivers to a chassis of a module housing including riveting each of the receivers in the set of solar receivers with the chassis of the module; 3) connection of the electrical wiring of the set of receivers inside of the module housing; 4) assembly and alignment of the patterned panel of Fresnel lenses onto the top of the module housing with placement pins at known fixed locations in a top lip of the module housing and the use of a laser for proper placement of the glass lens patterned panel relative to the stamped housing of the module; 5) assembly and alignment of the set of modules containing solar receivers to the paddle structure; 6) use of double nuts, shims or other dynamic leveling mechanisms to finely align and secure the set of modules in the paddle structure; 7) the paddle structure with the modules installed are shipped to the field to be installed; and two or more paddle structures form a paddle pair assembly on each two axis tracking mechanism.

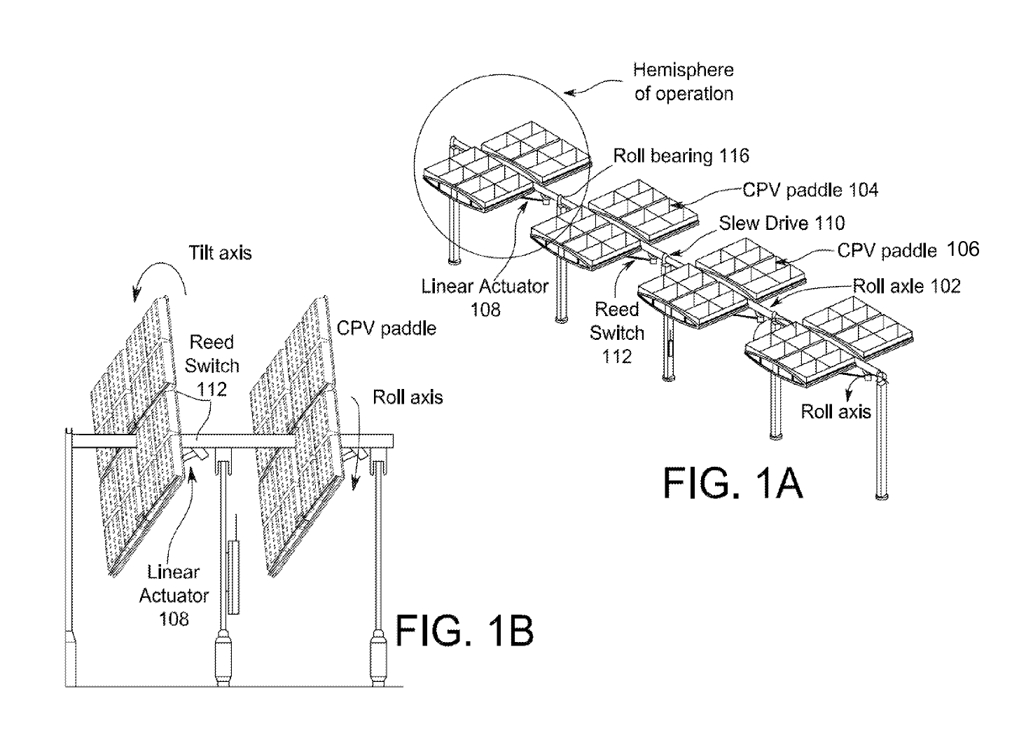

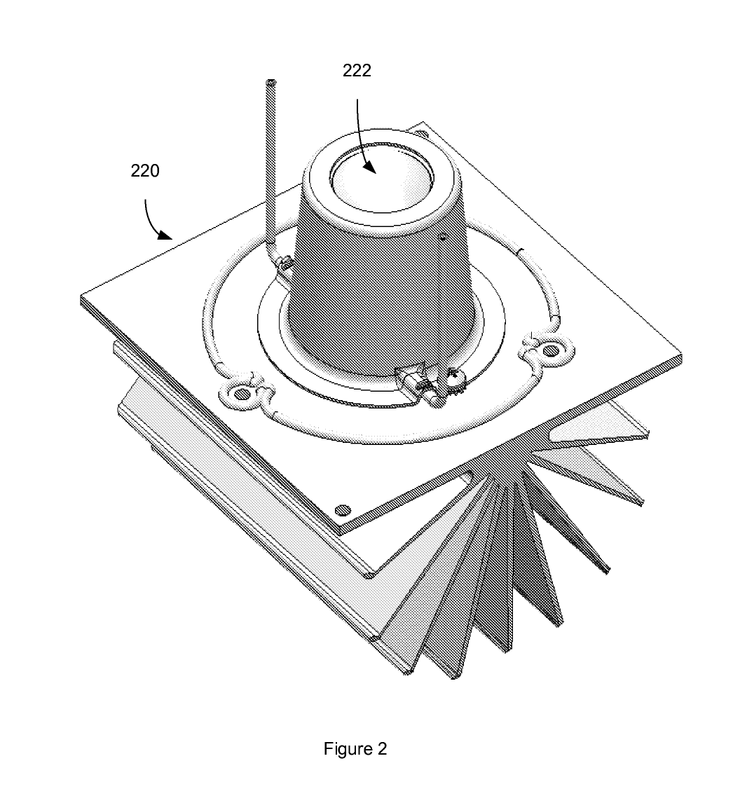

FIGS. 1A and 1B illustrate diagrams of an embodiment of a two axis tracking mechanism for a concentrated photovoltaic system having multiple independently movable sets of concentrated photovoltaic solar (CPV) cells. FIG. 1A shows the paddle assemblies containing the CPV cells, such as four paddle assemblies, at a horizontal position with respect to the common roll axle. FIG. 1B shows the paddle assemblies containing the CPV cells tilted up vertically by the linear actuators with respect to the common roll axle.

A common roll axle 102 is located between 1) stanchions, and 2) multiple CPV paddle assemblies. Each of the multiple paddle assemblies, such as a first paddle assembly 104, contains its own set of the CPV solar cells contained within that CPV paddle assembly that is independently movable from other sets of CPV cells, such as those in the second paddle assembly 106, on that two axis tracking mechanism. Each paddle assembly is independently moveable on its own tilt axis and has its own drive mechanism for that tilt axle. The drive mechanism may be a linear actuator with a brushed DC motor. An example number of twenty-four CPV cells may exist per module, with one to eight modules per CPV paddle, two or more CPV paddle structures per paddle assembly, a paddle assembly per tilt axis, and two to four independently-controlled tilt axes per common roll axis.

Each paddle pair assembly has its own tilt axis linear actuator, such as a first linear actuator 108, for its drive mechanism to allow independent movement and optimization of that paddle pair with respect to other paddle pairs in the two-axis tracker mechanism. Each tilt-axle pivots perpendicular to the common roll axle 102. The common roll axle 102 includes two or more sections of roll beams that couple to the slew drive motor 110 and then the roll beams couple with a roll bearing assembly having pin holes for maintaining the roll axis alignment of the solar two-axis tracker mechanism at the other ends, to form a common roll axle 102. The slew drive motor 110 and roll bearing assemblies are supported directly on the stanchions. A motor control board in the integrated electronics housing on the solar tracker causes the linear tilt actuators and slew drive motor 110 to combine to move each paddle assembly and its CPV cells within to any angle in that paddle assembly's hemisphere of operation. Each paddle assembly rotates on its own tilt axis and the paddle assemblies all rotate together in the roll axis on the common roll axle 102.

The tracker circuitry uses primarily the Sun's angle in the sky relative to that solar array to move the angle of the paddles to the proper position to achieve maximum irradiance. A hybrid algorithm determines the known location of the Sun relative to that solar array via parameters including time of the day, geographical location, and time of the year supplied from a local GPS unit on the tracker, or other similar source. The two-axis tracker tracks the Sun based on the continuous latitude and longitude feed from the GPS and a continuous time and date feed. The hybrid algorithm will also make fine tune adjustments of the positioning of the modules in the paddles by periodically analyzing the power (I-V) curves coming out of the electrical power output circuits to maximize the power coming out that solar tracker.

Note, optimally tracking the Sun with four independently moveable paddle pair assemblies on a solar array is easier and more accurate across the four paddle pairs than with a single large array occupying approximately the same amount of area as the four arrays. In an example, four or more paddles, each contains a set of CPV cells, and form a part of the two-axis solar tracker mechanism. Each of these paddles may be part of a paddle pair assembly that rotates on its own tilt axis. For example, both a first paddle structure containing CPV cells on a first section of a first tilt axle and a second paddle structure containing CPV cells on a second section of the first tilt axle rotate on the axis of that first tilt axle. Likewise, both a third paddle structure containing CPV cells on a first section of a second tilt axle and a fourth paddle structure containing CPV cells on a second section of the second tilt axle rotate on the axis of that second tilt axle. In addition, both the first and second tilt axles connect perpendicular to the common roll axle that universally rotates all of the tilt axles.

The two-axis tracker includes a precision linear actuator for each of the paddle pairs in the four paddle pairs joined on the shared stanchions as well as the slew drive connect to the common roll axle 102. A set of magnetic reed sensors can be used to determine reference position for tilt linear actuators to control the tilt axis as well as the slew motor to control the roll axis on the common roll axle 102. Each tilt linear actuator may have its own magnetic reed switch sensor, such as a first magnetic reed sensor 112.

The paddle structure has only a few components that need to be assembled to install and secure in place in the field on the tracker assembly. The four tilt axle and roll beam assemblies are supported by five stanchions, and have the one integrated electronics system to control that tracker assembly. The stanchions support the tracker assembly and are shared between CPV paddle pairs. Each paddle pair has its own tilt axis linear actuator to allow independent movement and optimization of that paddle pair with respect to other paddle pairs in the tracker assembly. The tilt actuators and the slew drive motor control the position of the tilt and roll angles of the paddles to orient the CPV cells such that the maximum incoming light is focused to the photovoltaic collectors/receivers in the paddle pair.

FIG. 2 illustrates a diagram of an embodiment of the assembled solar receiver. The assembled solar receiver 220 establishes an alignment of the secondary optic 222 to the photovoltaic solar cell.

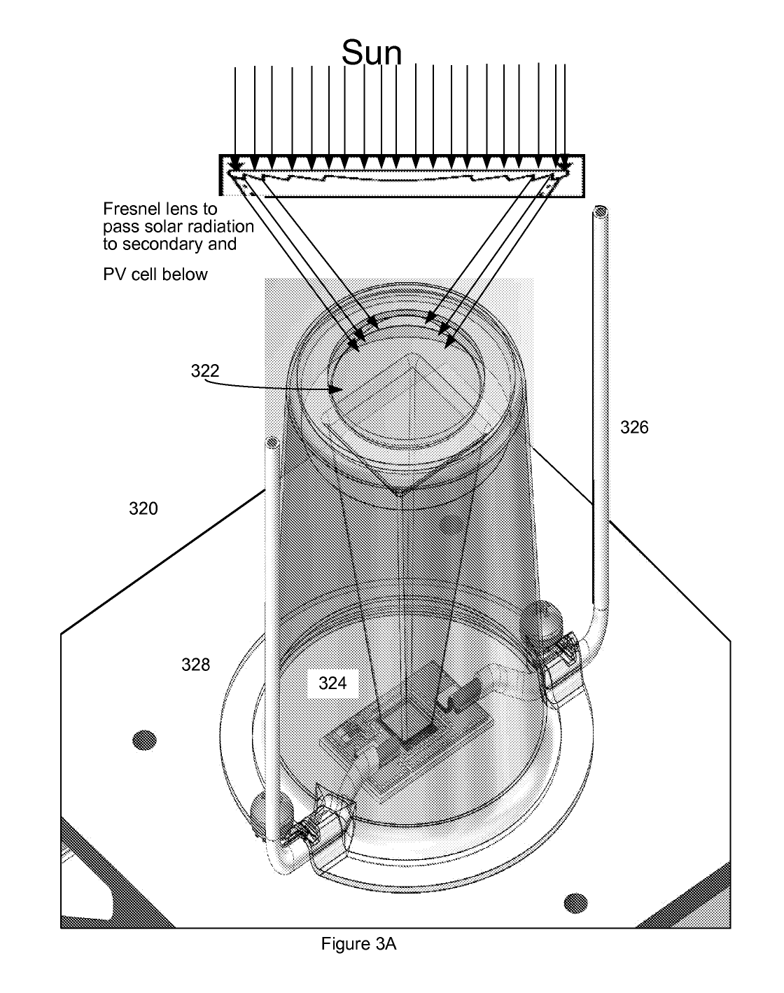

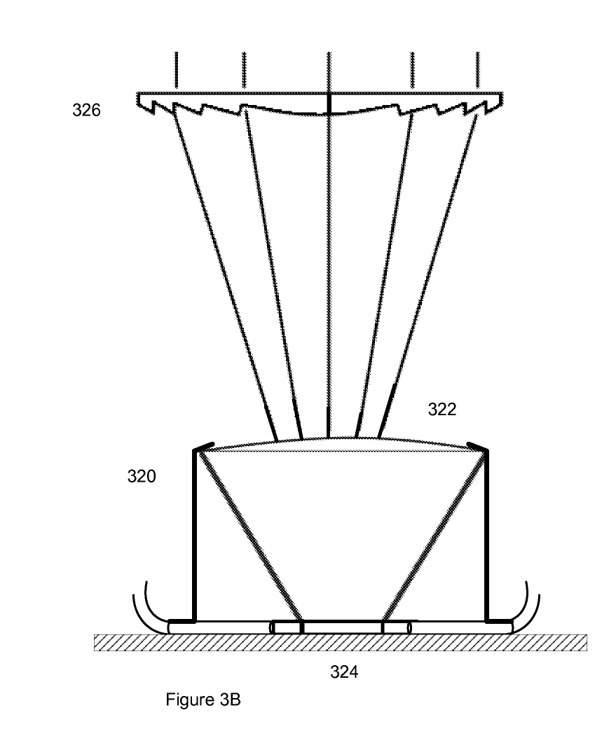

FIGS. 3a and 3b illustrate diagrams of an embodiment of an assembled and aligned solar receiver containing a concentrated photovoltaic cell. Referring to FIGS. 3a and 3b, the CPV cells, such as a first photovoltaic cell 324, each contained in a solar receiver 320 in an individual module are aligned in three dimensions with each other by the fabrication process. The individual parts making up the solar receiver 320 are 1) shaped, 2) sized, 3) keyed, 4) pinned and 5) any combination of these to fit together in only one way so that all of the solar receivers containing the CPV cells, such as 24, maintain their alignment when installed in a given CPV module. Each solar receiver 320 is assembled with mass produced parts that have tight manufacturing tolerances, and shaped and keyed to assemble each receiver in merely one way so that all of the CPV receivers have the substantially the same height, the same length, the same width dimensions, and same overall shape.

The solar receiver has an integrated heat sink, a cylindrical casing with a lip with indents, a linearly focused Fresnel lens 326, spacing set for the primary Fresnel lens, both primary and secondary AR coatings, an approximately two degree draft angle for the primary optic, a domed secondary concentrator optic 322 (snow cone design, which gives ±30 mm focal length tolerance, and gives ±1 deg acceptance angle at 90% point), a coupled multiple junction photovoltaic cell 324, and many other features. The high concentration may be for example, 1300 times the amount on the surface of the Fresnel lens. The solar receiver 320 houses the domed secondary concentrator 322 optically coupled to the multiple junction photovoltaic cell 324 as assembled.

The Fresnel lens 326 concentrates solar radiation to the photovoltaic cell 324 in the solar receiver 320 makes a CPV power unit. The Fresnel lens 326 focuses incident Sunlight to the secondary concentrator 320 optically coupled to a multiple junction photovoltaic cell 324. The secondary concentrator 320 has a domed shaped top portion and a trapezoidal shaped bottom portion with walls. The Fresnel lens 326 with its teeth redirects light rays to the domed shaped secondary concentrating mirror 322, which then reflects the concentrated beam of light to within the walls of the trapezoidal shaped portion of the prism and onto the multiple junction photovoltaic cell 324. The domed shaped top portion and trapezoidal bottom portion provide a larger acceptance angle than the trapezoidal bottom portion by itself, while also providing good homogenization of the light intensity across the surface of the multiple junction PV cell. The domed shaped top portion and trapezoidal bottom portion merely fit centered within the solar receiver casing in one way. The casing of the receiver 320 with its shaped circular lip 328 can only fit over the underlying secondary optic 322, photovoltaic cell 324, and wiring in one way. The individual parts of the solar receiver containing a CPV cell assemble and fit together to maintain their alignment. When assembled properly, the alignment of the CPV is maintained and each receiver is very close to identically matching the height of another receiver. Tight manufacturing tolerances on the mass production of the parts forming each assembled solar receiver causes each assembled solar receiver to be nearly identical to another assembled solar receiver. Thus, the concentrating photovoltaic (CPV) technology converts solar energy into DC power out very efficient under medium or high levels of DNI (direct normal irradiance). Each solar power unit may include: a primary optic, a secondary optic, a multi-junction photovoltaic cell and a heat sink for improved thermal performance for the photovoltaic cell. The primary optic concentrates the sun's light by a factor of 1,300× using a tempered glass Fresnel lens that features low sensitivity to temperature and chromatic aberrations. The secondary optic is a domed shaped top with trapezoidal bottom precision-formed optic that has a wide acceptance angle to simplify tracking requirements while delivering maximum power. The multi-junction photovoltaic cell has small dimensions and efficient passive thermal management to help maximize performance even at high temperatures. Note, regions with the greatest solar energy potential tend to be hot, which has an adverse effect on the efficiency of traditional photovoltaic solutions. However, the multi-junction solar cells have a very low temperature coefficient, which allows these solar cells to maintain significantly higher efficiency than other photovoltaic solutions.

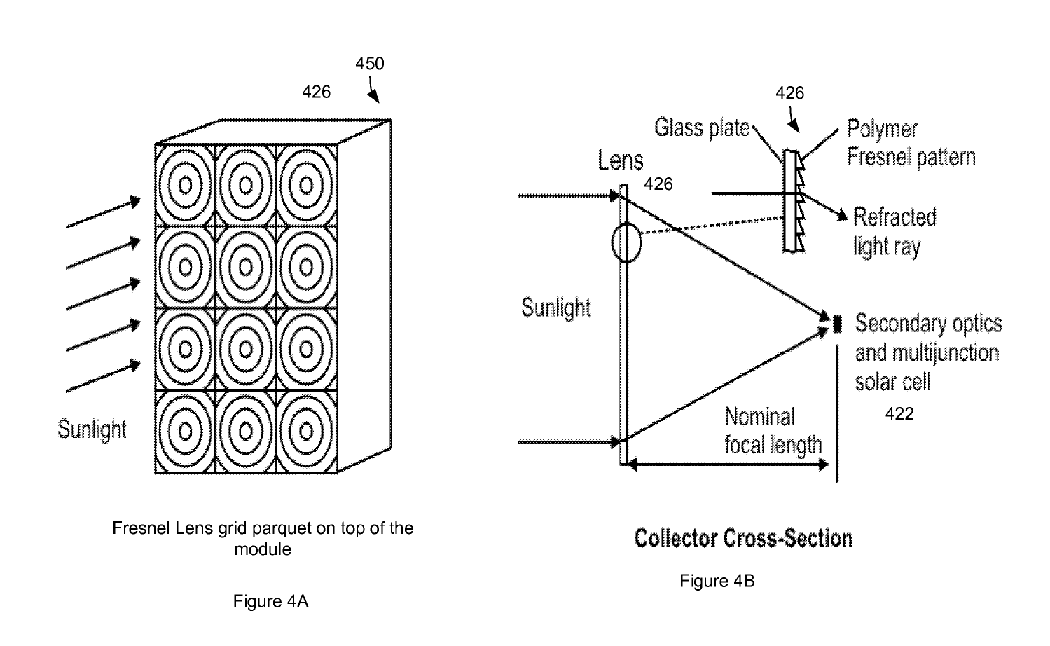

FIGS. 4A and 4B illustrate diagrams of an embodiment of a Fresnel lens optically coupling to the solar receiver. The chassis of the module 430 has an increased chassis depth from the patterned panel (parquet) with the Fresnel lenses for a focal length that optimizes efficiency and has a decreased long dimension, which fits loaded in the paddle in shipping container. Each Fresnel lens 426 optically couples to its own secondary optic 422.

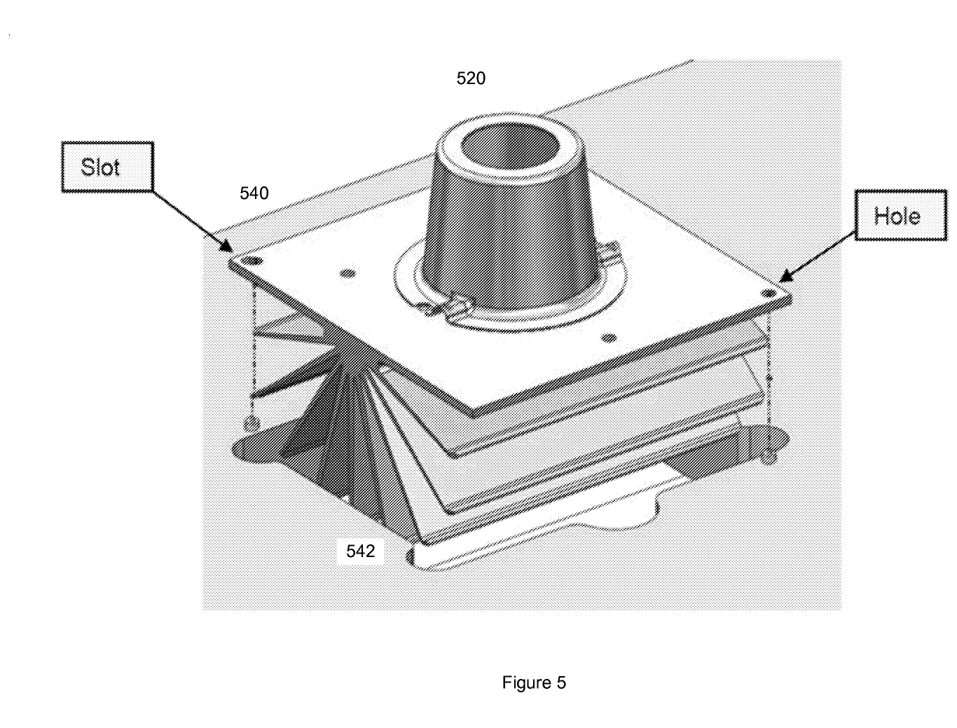

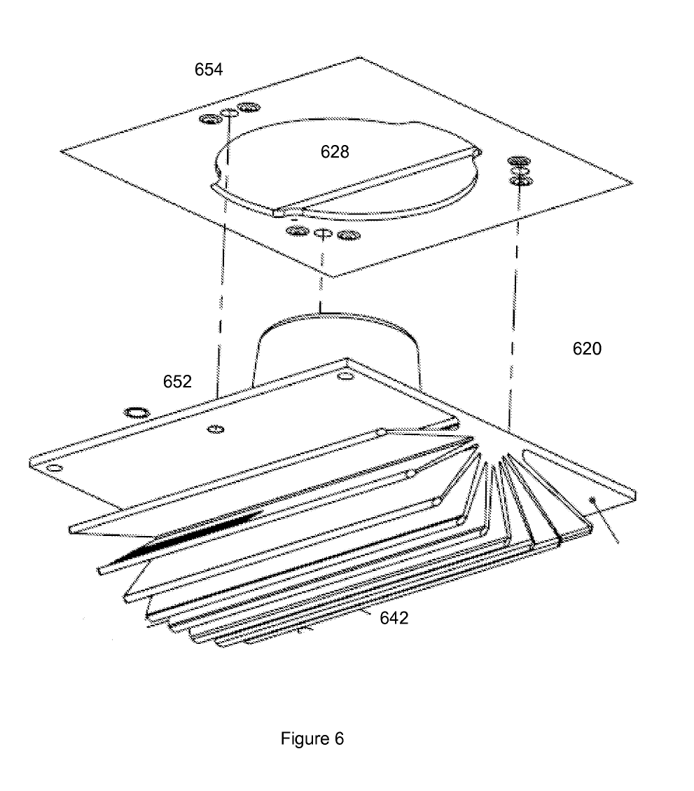

FIG. 5 illustrates a diagram of an embodiment of the casing of the solar receiver 520 mating to a flat heat spreader 540 inside the module and a heat sink 542 extending outside the module. The PV cell mounts on the heat spreader/base plate 540 and the heat sink 542 penetrating the chassis of the module. The flat heat spreader 540 has a hole and slot to enable installation into the ‘receiver to module fixture plate’ by the heat sink in one way. The cavity of the fixture also merely allows the heat sink 542 of the solar receiver 520 to be installed in the ‘receiver to module fixture plate’ in one way.

FIG. 6 illustrates a diagram of an embodiment of the solar receiver attaching from the bottom to the chassis of the module. The heat sink 642 is large and optimized to increase performance. Adequate passive cooling occurs by placing the heat sink 642 on the backside of the module.

The solar receiver 620 is more efficient and better than other designs. The photovoltaic cells have a geometric concentration secondary optic, a wide acceptance angle (>1°), improved thermal performance due to cell size to heat dissipation surface area, and advanced thermal design of cooling fins on receiver.

Due to the solar receiver's design, the power output and operating voltage from the photovoltaic cell itself does not vary too much (fairly independent of) with changes in outside temperature; and thus, is more predictable with this temperature stability.

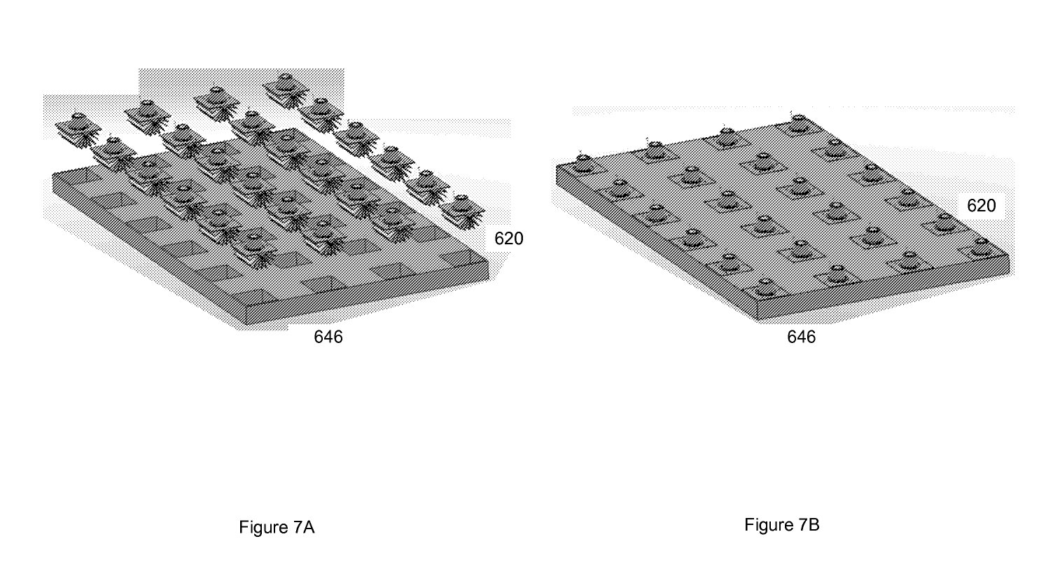

FIGS. 7a and 7b illustrate diagrams of an embodiment of an initial step of the assembly of a module with multiple receivers set in place on a receiver to chassis fixture. A set of solar receivers includes multiple solar receivers including a first solar receiver 620. A set of solar receivers, such as 24 receivers, assembled and aligned to a chassis of a module housing. Install 24 Receivers optionally with Silicone already dispensed on them into an empty ‘receiver to chassis alignment fixture’ 646. The ‘Receiver to Chassis Attachment fixture’ 646 establishes pre-placement of receivers into the chassis of the module so they will all be at the same height, and on the vertical and horizontal axis. On the fixture 646, the receiver may be placed and orientated in each location on the fixture 646 in merely one way due to the size and shape of the receivers themselves and the oval slot and circular placement holes in the heat spreader of the solar receiver.

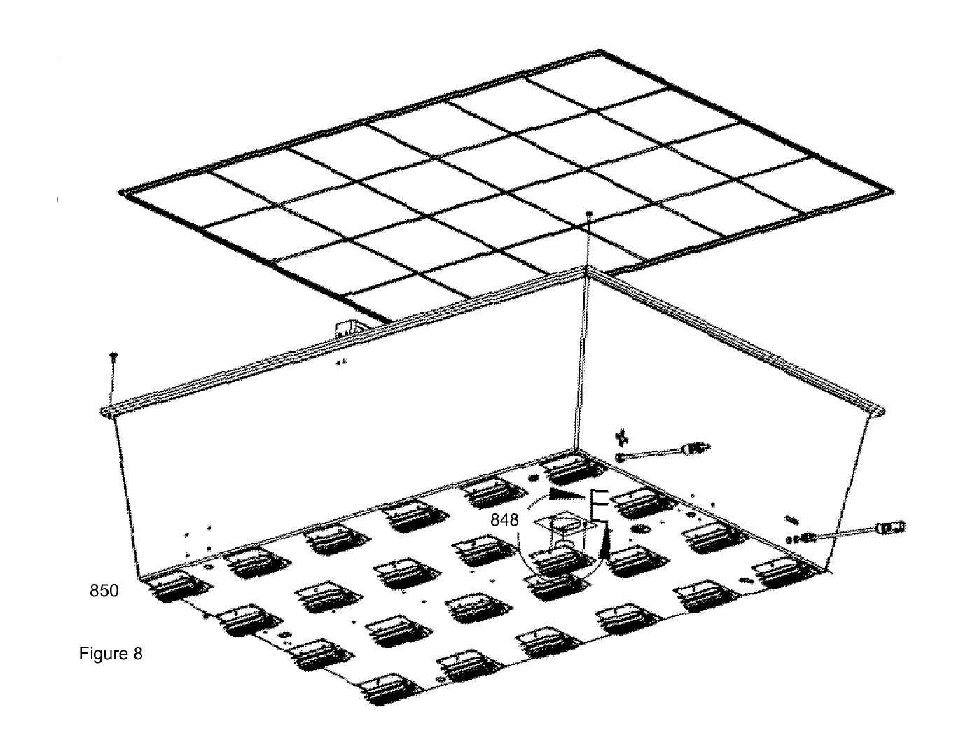

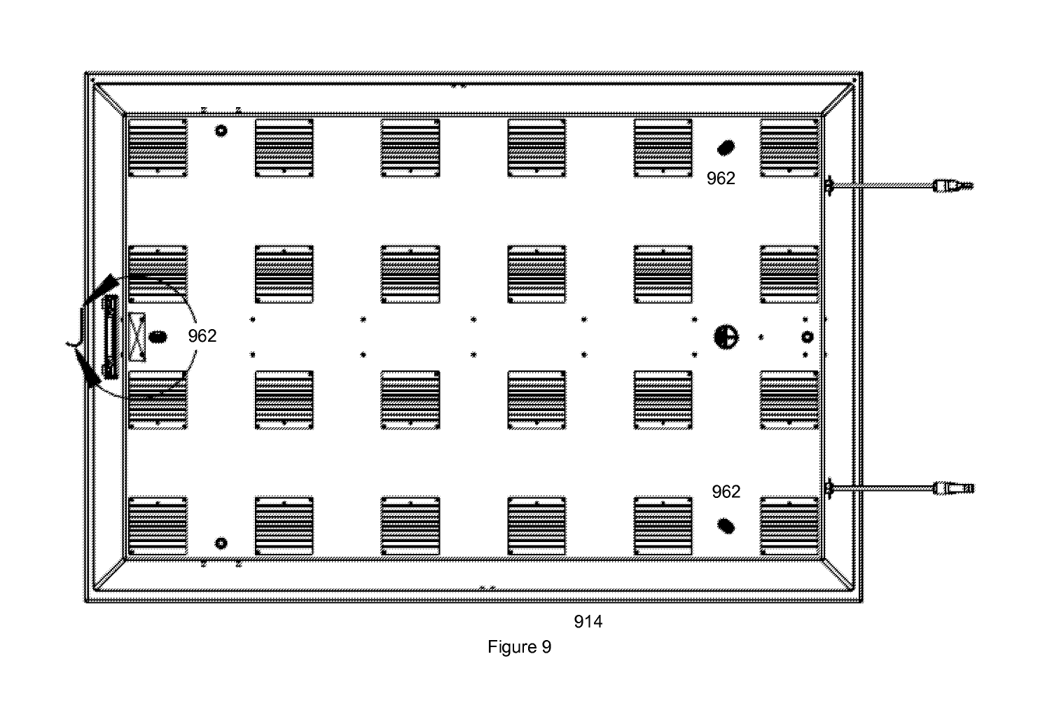

The multiple receivers, such as 24 receivers, are put onto a fixture tool 646 to be installed into the stamped housing of the module. Ensure all 24 receivers are placed flat on the fixture 646. Referring to FIG. 5, a hole and slot have been precisely been located on the casing of the receiver to Align with Alignment Pin Holes on Fixture. The receiver to chassis alignment fixture ensures the solar receiver is installed in its proper orientation via the oval slot, circular hole, and the shape matches the hole in the fixture so the receiver with the heat sink cannot rotate with the heat sink in the slot. Referring back to FIG. 7B, inspect each receiver hole and slot and verify the pins in the fixture plate 646 are in them. The installed receivers fit directly into locations 1-24 stamped into the chassis of the module (See FIG. 8 with the fixture visually removed and all but one received installed in place).

FIG. 8 illustrates a diagram of an embodiment of a module assembly created with a rectangular grid containing a set of, for example 24, individual concentrated photovoltaic cells each in its own solar receiver. A jig tool stamps the module casing template with placement cavities for the 24 receivers in the module such as a first placement cavity 848. The same tool stamps the same pattern into each module template to set the depth, vertical, and horizontal alignment of the 24 identical receivers when installed in the module. Thus, each module which has been fabricated to have the CPV solar receivers installed from the ‘Receiver to Chassis Attachment fixture’ that are aligned vertically, horizontally, with respect to the other receivers installed in the module template.

Thick spacers may be placed between the receivers on the surface of the fixture to accommodate a single tooling ball at that end. The chassis of the module 850 may have a tendency to flex and come in contact with the silicone sealant on the receivers without these spacers. Note, the blocks on perimeter of chassis are also used to guide the chassis into approximate position when mating the receivers on the fixture to the module 850. The lip of the receiver can be sealed in place with a sealant.

The prepared chassis is lowered onto the ‘receiver to chassis alignment fixture.’ Use the 4 guide blocks in each corner of the fixture to help guide the chassis into position. Lower the chassis onto the set of solar receivers with fresh Silicone Sealant on them and prevent the chassis from contacting the Silicone sealant of receivers. The chassis of the module 850 is lowered evenly to ensure all three alignment balls on the fixture contact the corresponding grooves in the bottom of the chassis at the same time (see FIG. 9 for the grooves 962 in the bottom of the chassis 914). Processing the set of receivers when attaching the set of receivers to the chassis of the module 850 all at the same time helps to ensure all of the solar receivers in the module 850 are aligned with each other in the three dimensions. In addition, the kinematic grooves in the chassis of the module 850 are configured to allow the solar receivers on a fixture tool to couple into the chassis in only one way. Also, the fixture has matching kinematic balls rising off the surface of the fixture.

As discussed the module template has placement cavities including the first placement cavity 848. Referring to FIG. 6, further the shape of the receiver has a lip with indents in the shape of the lip that match a placement cavity 628 stamped into the chassis of the module. Also, multiple holes 652 in the base plate/heat spreader of a solar receiver are matched in shape and location to corresponding sets of multiple holes 654 in the chassis of the module. The CPV cells in the receiver are installed in the horizontally level surface of the module and in parallel alignment with each respect to each other. Each receiver fits into the cavity and lip rest on the horizontal surface of the module template. When sitting flat on the horizontal surface the vertical axis of the receiver is maintained.

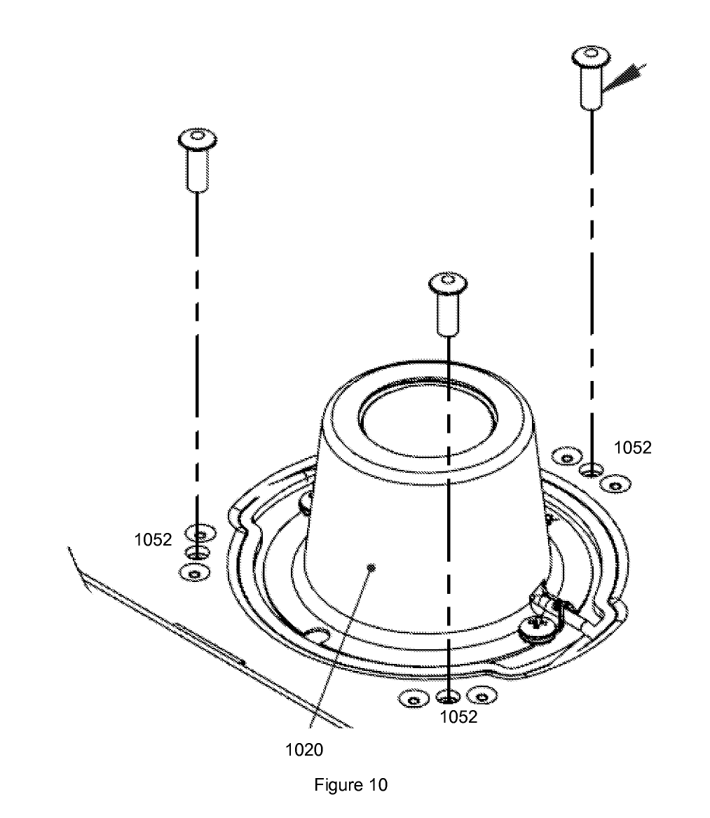

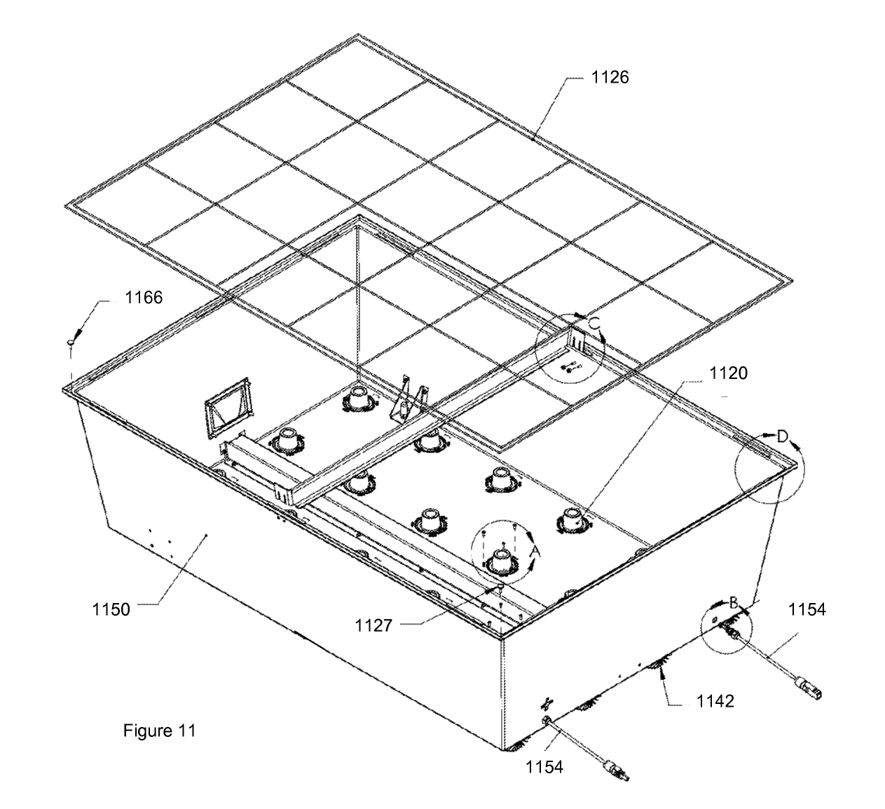

FIG. 10 illustrates a diagram of an embodiment of a solar receiver 1050 having sets of precisely drilled holes 1052 in the heat spreader of the receiver the exactly correspond to holes in the chassis of the module template.

FIG. 11 illustrates an exploded view of a diagram of an embodiment of a module having a set of solar receivers 1120 installed, a patterned panel of Fresnel lenses 1126, a vent cover and other features. FIG. 11 illustrates a first solar receiver 1127 in the set of solar receivers having rivets put into the precisely drilled holes in the chassis of the module template that exactly correspond to the holes in the heat spreader of the receiver.

Each of the receivers is then riveted with the chassis of the module. Riveting each of the receivers in the set of solar receivers to the chassis of the module mechanically secures the assembled and aligned set of solar receivers to the chassis of a module. Riveting allows for a tighter alignment of the receiver relative to known location in the chassis of the module than screws or nuts and bolts. Alignment of CPV receivers is verified and then secured when fixed in-place in the stamped module template. Also, mechanisms such as 1) the precisely drilled holes in the module template and 2) the fabricated lip of the receiver direct where to rivet the receiver to the horizontal module.

In an embodiment, insert rivets into all 24 receivers starting with the 4 corner receivers (1, 6, 19, and 24) then continuing on to 2-5 first, 7-12 second, and then proceeding to the other side of the chassis to complete receivers 13-18 and finally 20-23. Install any post to attach the receivers. All rivet placement and post-attachment hold a receiver in position inside the chassis. When receivers 1-24 are completely loaded with rivets, remove the thick spacers from under the module and lower all 3 tooling balls until the module contacts the receivers. Press downward to eliminate the gap between chassis and receiver, and then fire the rivet gun. Inspect the head of each rivet to ensure no gap exists between the rivet head and the bottom surface of the chassis. When all receiver assemblies have been riveted to the chassis and any residual RTV sealant has been wiped away, the chassis assembly is lifted up and out of the ‘receiver to chassis alignment fixture’ and moved for the next step of receiver wiring of the CPV cells. The module template and receivers have been permanently secured together to form a module with a set of solar receivers installed. The module has a positive and negative output lead 1254 for that set of receivers installed in the module.

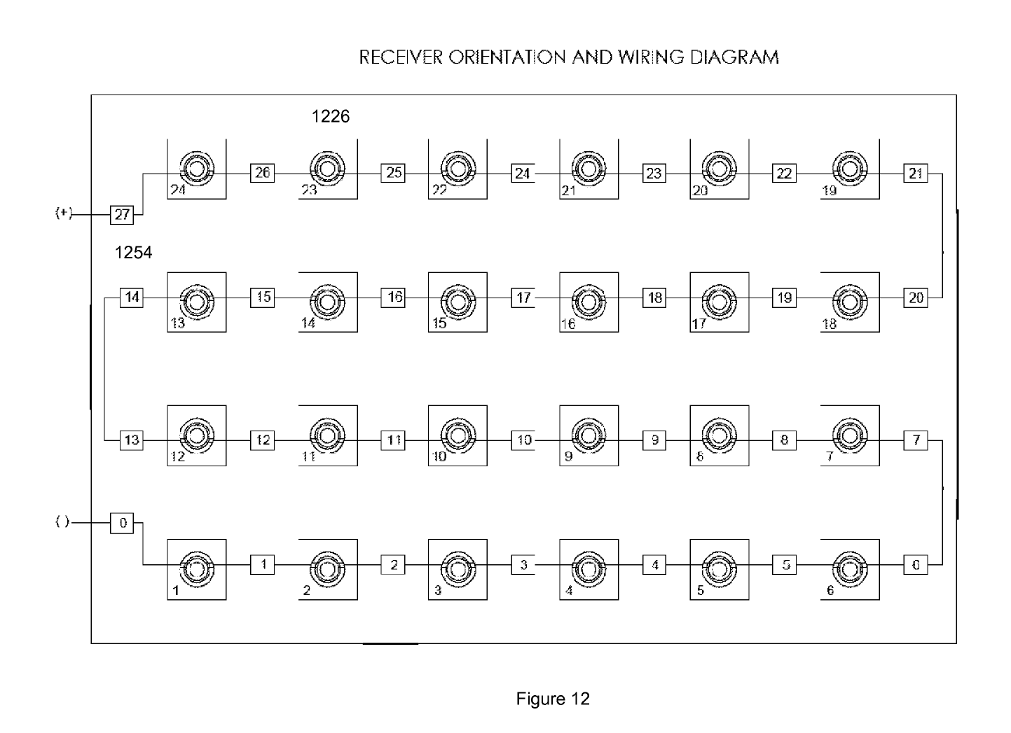

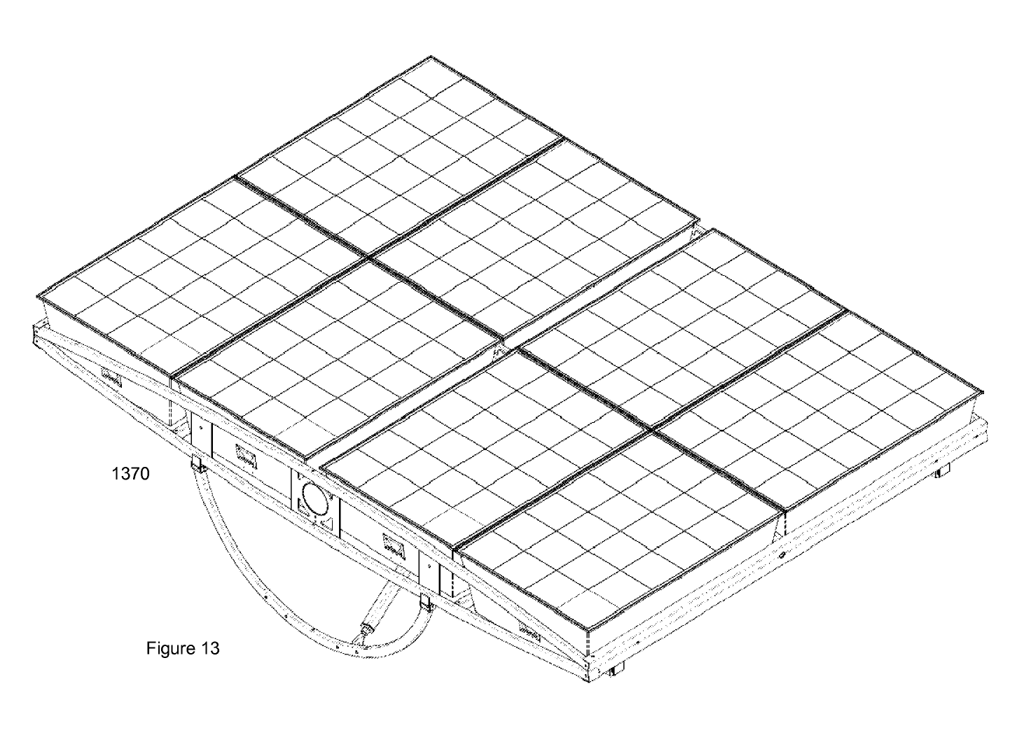

FIG. 12 illustrates a diagram of an embodiment of a module assembly with all the solar receivers wired together internally within the module. The connection of the electrical wiring of the set of receivers 1226 inside of the module housing while in the fabrication facility occurs. The module's wiring has an inter-receiver connector approach to keep all of the wires connecting the multiple receivers electrically in parallel, electrically in series, electrically in series-parallel, and any combination of these, and merely the plus and minus DC output voltage leads 1254 from the set of the receivers within the module are externally exposed outside the housing of the module. (See also FIG. 11) Elimination of individually wiring each of the hundreds or thousands of solar cells during the field installation occurs by doing the wiring and connections between these cells in the manufacturing facility itself. The internal electrical connections to each solar receiver may be crimped inside the chassis and have heat shrink tubing over the crimped and soldered connections.

Referring to FIG. 11, the assembly and alignment of the glass Fresnel lens patterned panel 1126 onto the top of the module housing occurs with placement pins 1166 at known fixed locations in a top lip of the module housing and use of a laser for proper placement of the glass lens patterned panel relative to the stamped housing of the module. The glass Fresnel lens patterned panel may 1126 be organized into a grid of individual Fresnel lenses on that patterned panel (See also FIG. 3). The grid of Fresnel lens may cover each module template with the set of receivers installed. The Fresnel lenses for all of the individual solar receivers installed into the CPV module are manufactured from the same tool. Thus, each Fresnel lens in the grid of lenses for each of the individual solar receivers installed in the module template should have the same characteristics.

In an embodiment, the patterned panel 1126 attaches to the module using the laser to set the alignment of the Fresnel lens to its corresponding solar receiver is as follows.

Initially, verify laser beams are perpendicular to the squaring jig on the laser alignment table prior to aligning every patterned panel to each module. Turn on power to the multiple LED cross-hair laser assemblies. Using the two beam tilt adjustment screws, adjust the laser level until the reflected beam is centered on the laser output. This will ensure the beam is perpendicular to the squaring jig surface under a laser beam where the module will rest during alignments. Once placed, push the module assembly into a reference corner to ensure the module is up against the squaring fence on both sides. Install securing bolts through the bottom of the squaring jig into the module mounting bolt locations and tighten only hand tight. Insert an alignment pin into both holes on the upper perimeter of the module. Slightly tap the suction cup holders on the patterned panel to center the Fresnel lenses through which the laser beams pass such that each beam is passing through the center ring in the lens (approximately 8 mm diameter). This will require “compromising” amongst all 3 locations to find the averaged best fit for each patterned panel to a chassis. When the patterned panel is aligned, press fit both alignment pins to the patterned panel. Press the pin heads against the under glass surface sufficiently to ensure a strong adhesion. Lower the side with alignment pins down first giving priority of insertion to the corner of glass near the reference corner of the laser alignment squaring fixture. When both pins are started in their holes, lower the entire patterned panel onto the chassis. Silicone can be dispensed on the Module between the patterned panel and the module. Press down the patterned panel at all locations to ensure adequate adhesion. Break off the removable portion of the alignment pin shafts while the RTV5818 Silicone is still wet. Unclamp the squaring clamp, and unbolt the retaining bolts. Now an individual module with a set of receivers has been constructed.

An individual module has been created with a pre-alignment of the CPV cells with respect to each other, by being level to the same plane, all the same height, allowed to couple into the chassis in merely the same orientation and secured into the orientation. Thus, the CPV cells in an individual module are aligned in three dimensions with each other by the fabrication process, and use of keyed parts shaped or pinned to fit together in only one way so that all of the solar receivers containing the CPV cells maintain their alignment when installed in a CPV module. The pre-alignment of the CPV cells occurs when each receiver is installed in the modules, and this alignment is maintained when modules couple to the paddle structure; and accordingly, these pre-alignments of every CPV cell in the paddle structure minimize installation time of the entire system in the field and also improves the pointing accuracy over the entire set of CPV cells in the field.

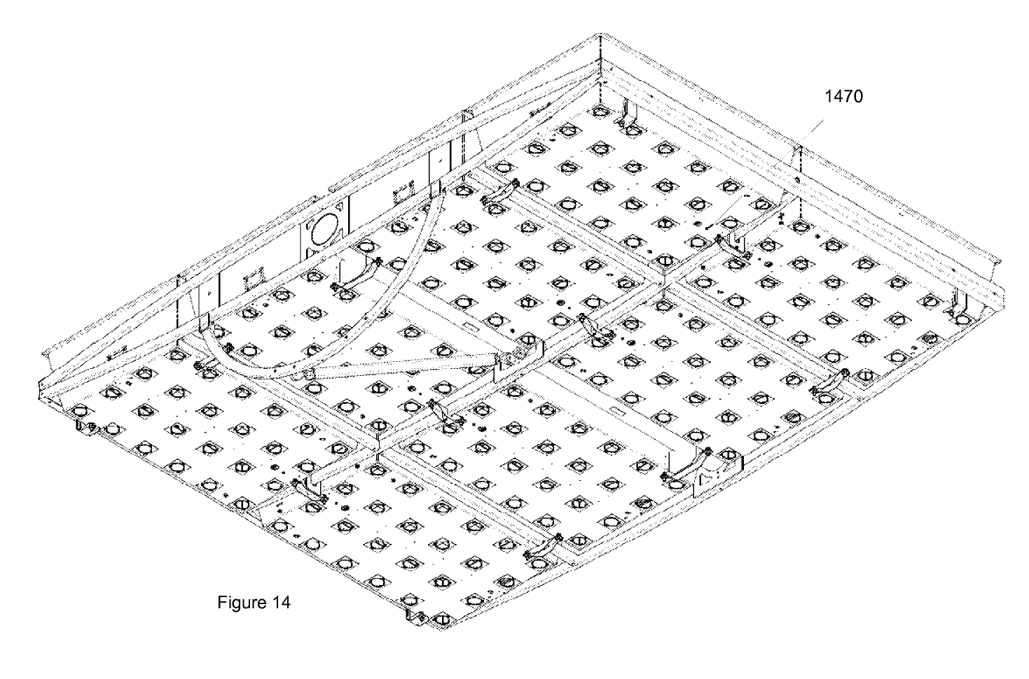

FIG. 13 illustrates a top down perspective view of an embodiment of an assembled paddle structure. FIG. 14 illustrates a bottom up perspective view of an embodiment of an assembled paddle structure. Each paddle structure 1370, 1470 contains between one to eight CPV modules as part of the solar array of the two-axis tracking mechanism, which are stamped to create rows and columns of insertion holes for the CPV cells contained in the solar receiver, and take advantage of being mass produced.

Module Installation into the Paddle Structure

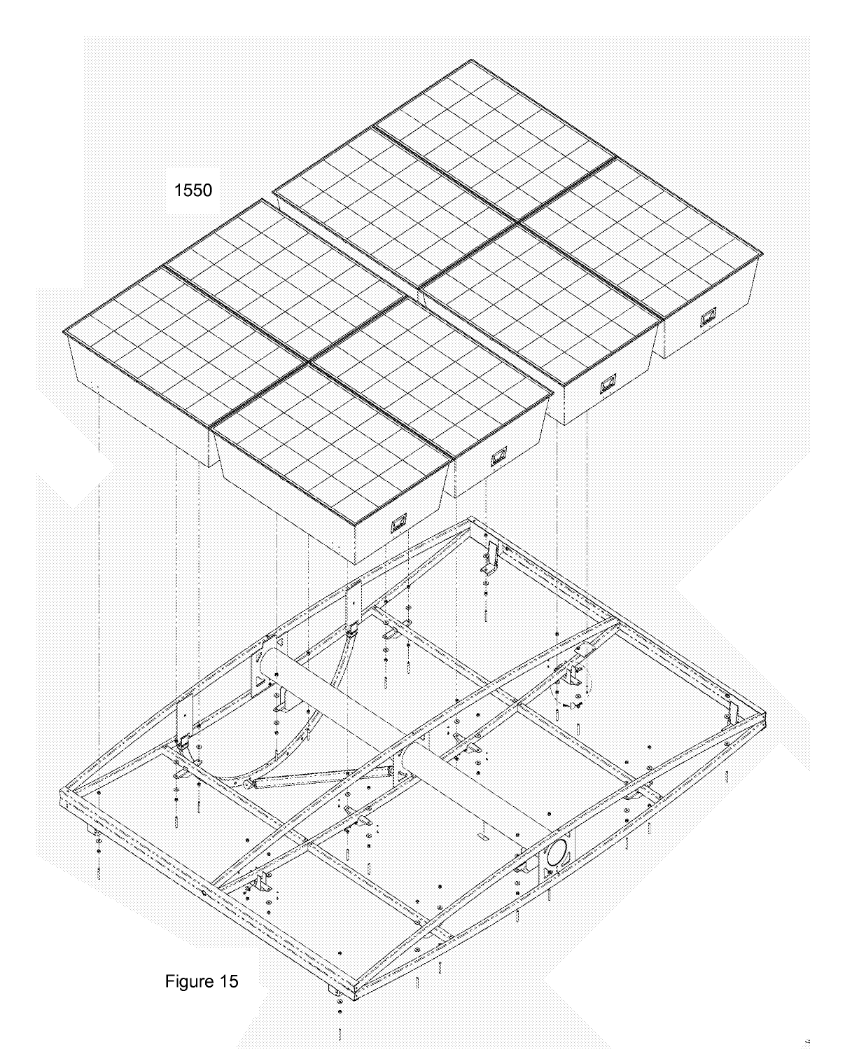

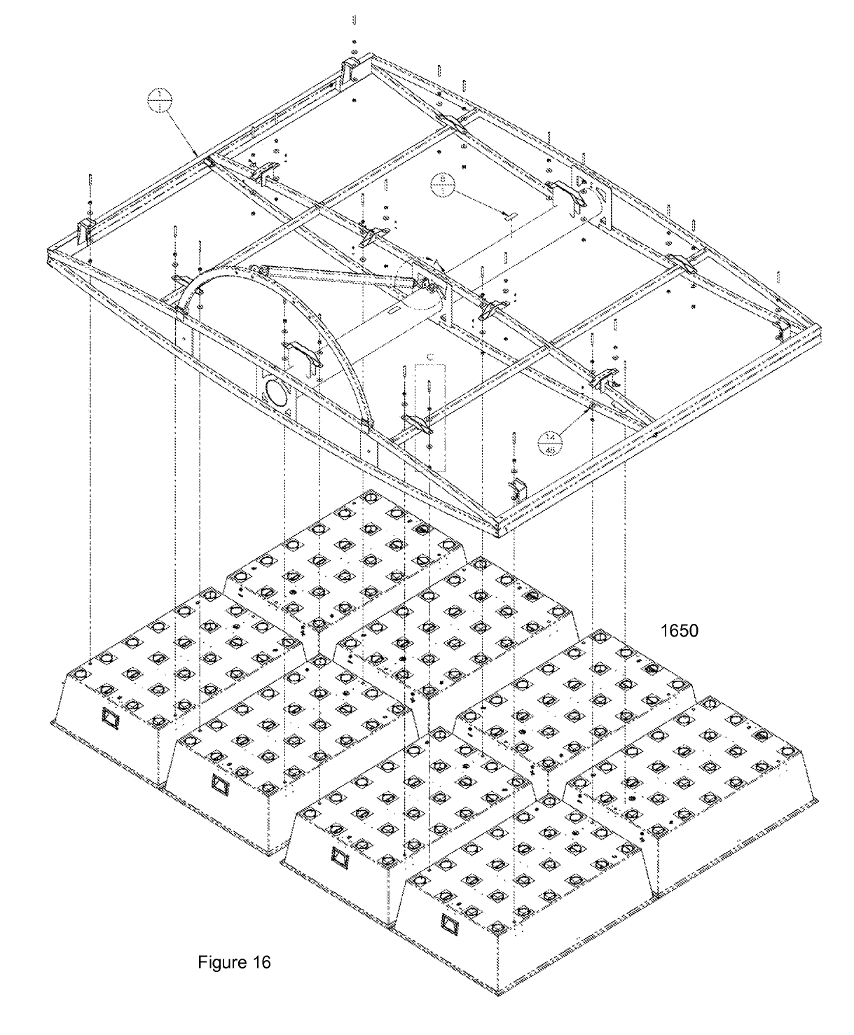

FIG. 15 illustrates a top down perspective exploded view of an embodiment of an assembled paddle structure. FIG. 16 illustrates a bottom up perspective exploded view of an embodiment of an assembled paddle structure. Assembly and alignment of the set of one or more modules containing CPV cells to the paddle structure including a first module 1550, 1650. Double nuts, shims, or other types of dynamic leveling mechanisms may be used to finely align in the set of modules into the paddle structure, and to securely maintain this alignment within the paddle structure. Overall during the installation process, the frame of the paddle structure rests upon a leveling fixture with the set of modules also resting on the leveling fixture.

The one or more modules, such as 8 modules, contained in the paddle structure are aligned and parallel in the plane of at least the diagonal Z dimension with each other as they are prepared to be attached to the tabs and brackets of the skeletal paddle structure on a leveling fixture. The modules loaded with the set of solar receivers resting on the leveling fixture, mechanically secure to the frame of the paddle structure via a dynamic leveling mechanism such as 1) shims between a tab bracket of the frame of the paddle structure and a threaded insert in a chassis of the module, 2) a threaded stud and double nuts between the bracket of the frame of the paddle structure and the threaded insert in the module, and 3) any combination of both that is used to set and then maintain an alignment of a given solar receiver with respect to any other solar receiver in that paddle structure. The module has a number of threaded inserts in the casing of the module that a bolt can couple through the frame of the paddle into the module to secure the module in place and roughly level on the frame of paddle. Multiple tab brackets on the frame of the paddle are aligned to corresponding threaded holes/inserts in the modules to create multiple connection points, such as 24 (3 per module) to set the alignment of the modules in the frame of the paddle in the three dimensions. The threaded inserts in the casing of the module include at least but not limited to 1) a riveted nut inside or on top of the hole, or an 2) actual a hollow casing with a threaded interior, or similar threaded hole. A number of washer or other type of shim may be placed between the threaded inserts and the holes in the frame of the paddle. Alternatively, lock nuts, or lock washers and nuts may be placed on each side of the bracket of the paddle frame coupling the thread between the threaded insert of the module and the frame of the paddle. Once the modules are installed into the paddle structure, then the paddle structure is constructed such that its set of CPV cells contained in the paddle structure maintain their alignment in three dimensions when installed in the paddle structure.

Nonetheless, some bowing and unlevel surfaces may exist in the manufactured paddle. A module to paddle structure may be dynamically aligned then and maintained via 1) shims such a washer, 2) use of a double nutting technique, or 3) any combination of both. The modules are placed on a support leveling fixture. A module level adjustment occurs by placing shims in the gaps between the modules and the paddle structure, or securing nuts in place between the bracket of the paddle structure and a given module when all of the modules in the paddle structure measure out to be level with respect to each other. Overall, the CPV cells aligned in the modules and then the modules all aligned in the three dimensions contained within the paddle structure are designed to produce an optimum amount of power based upon the alignment of the patterned panels of each module to the multiple solar receivers contained with each module, and each module being aligned to all of the other modules within the paddle structure. An example module to paddle structure process using a leveling fixture may be as follows.

Initially, level the leveling fixture and place modules onto the leveling fixture.

Ensure the leveling fixture for the CPV modules is level. Verify all eight module support plates are level on the leveling fixture. Ensure the leveling fixture is level in all axes, horizontally in both length, width, and centerline, diagonally, and then vertically. If not, turn the adjustments until the leveling fixture is. Use of straight edges and level tools can be used to measure and verify the level of the leveling fixture.

Next, place modules onto ‘Module to Paddle structure leveling Fixture’ as follows:

Clean module patterned panels and Module leveling plates. Place modules onto the assembly fixture. Lower each module into a reference corner first, and then rotate/set into position on the glass surface. Note that in all cases, the centered mounting hole on each module faces the center of the assembly fixture. Spacers in the fixture are used to define gaps between modules.

Place modules on leveling fixture in order such as 2, 3, 6, 7, etc. Each plate is labeled with the module location. All 8 modules should be placed into position on the ‘Module to Paddle structure fixture.’ Place washers onto each module mounting hole prior to paddle placement. These washers are critical to achieving required torque settings on module mounting screws.

The Process of coupling a paddle structure onto the eight modules on the leveling fixture.

Using an overhead crane/gantry system, orient the Paddle structure with its hoop oriented towards the “curved bracket hoop” side of the module to Paddle structure fixture . . . on the ground next to the Paddle structure fixture. Place the Paddle structure on the floor with the hoop side facing up. Install Y-support mounting brackets in corners of the paddle frame. Slowly lower the Paddle structure into position on the modules. As the Paddle structure begins to contact either the nests for the center tube . . . or the module chassis, the Paddle structure should be manually balanced and guided into position on the assembly fixture. Once the paddle is in full contact with the self-centering nests and/or modules, the entire weight of the paddle will come to rest on the support blocks on the leveling fixture to allow fine movements and adjustments to the modules.

### Attach Modules to Paddle as Follows:

Inspect paddle placement and all 24 mounting locations for excessive gaps between module bottom and mounting bracket. If gaps appear to be greater than a first threshold amount, reject the paddle. All of the modules have threaded inserts put into that module into the holes pre stamped to receive an insert. The threaded insert is enclosed at the bottom of the threads to keep water and air out of the module space. Measure the tube height as shown below.

If height variance is greater than a second threshold amount, such as 1 mm, the paddle will need to be tilted using the support posts underneath to lift up the lower side. If the height variance is greater than a third threshold amount such as 3 mm, the paddle must be rejected due to the gap between modules and paddles becoming excessive.

Install a total of 24 Cap Screws into mounting holes along with split washers. Install bolts.

If one of the first four bolts does not line up with the chassis mounting rivet, move either the module (+/−1 mm adjustability) or the paddle (some adjustability due to larger diameter hole size) to bring the holes into alignment. If the holes still do not align, reject the Paddle structure noting which bolt location is out of tolerance.

If one of the remaining 20 bolts does not align to insert the bolt, attempt to adjust the module and/or paddle to accommodate the offset. If the off-set is gross (more than 2 mm), after attempting module/paddle adjustments, reject the Paddle structure.

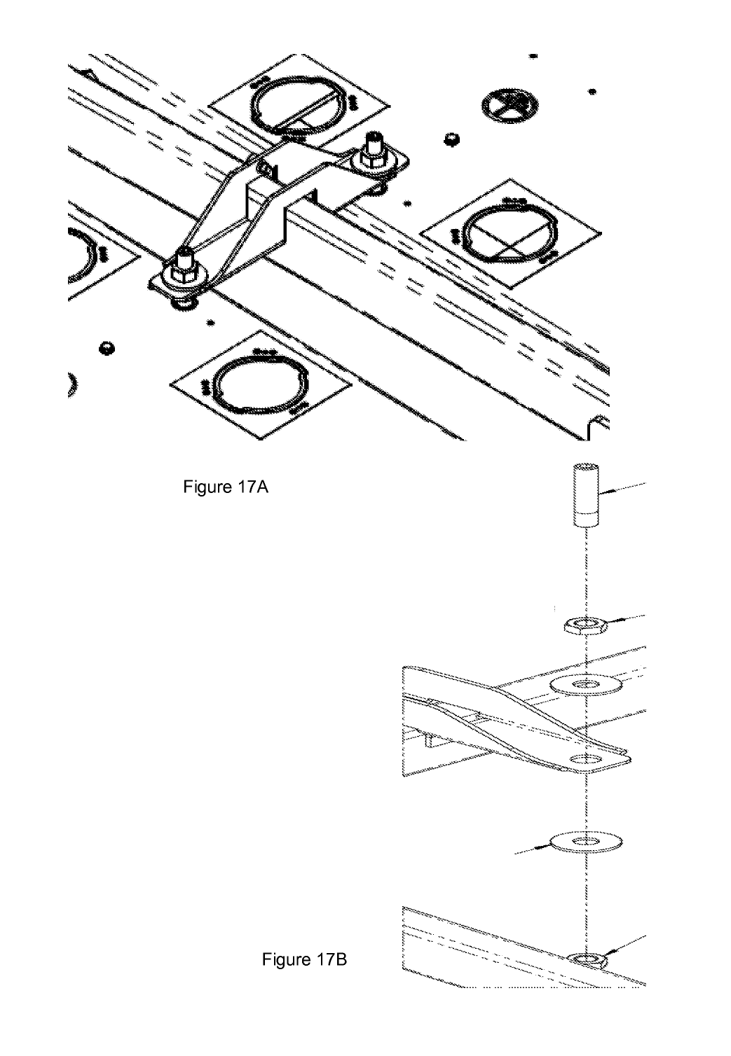

FIGS. 17A and 17B illustrate diagrams of an embodiment of double nutting across a bracket on the skeletal frame of the paddle structure to the threaded insert of the module. FIG. 17A shows the threaded stud going through the bracket into the threaded insert of the module and the nuts on both sides of the bracket. FIG. 17B shows more of an exploded view of the same. Hand tighten nuts on each side of the bracket and at the connection to the module to loosely secure the level conditions of the modules in the z plane by the nuts locking the modules to the frame of the paddle in this level condition. Alternatively, when all 24 bolts and split lock washers have been inserted by hand, fill gaps with 0.5 mm thick SS shims until no more can be fitted.

The leveling fixture creates the module planarity and the shims or doubling nutting locks this condition in place to yield improved power collection capability. Each paddle structure has a skeleton frame that couples to one or more modules that each contain the set of solar receivers arranged in a grid like pattern that are pre-aligned in at least one or more dimensions with each other during the fabrication process when the concentrated photovoltaic cells are installed in the paddle structure. The modules were assembled to maintain the alignment of the CPV cells within each module, and then the leveling fixture places all of the modules at that same alignment, and then the double nuts and or shims mechanically lock the modules in that alignment when coupled to the frame of the paddle structure.

After hand aligning the modules in the paddle structure, then the modules are torqued and potentially liquid lock tighten or welded to secure the modules into their aligned position. Tighten all Cap Screws to 25 ft-lbs using a torque wrench fitted with the proper Metric socket for the bolts and nuts. Tighten all 3 mounting bolts on each module as a group before moving on to the next module. Tighten modules in the same sequence as module placement onto the Module to Paddle structure Fixture.

When the Paddle structure has been secured successfully to all 8 modules, obtain a paddle serial number label and attach it to the main tube. If shims were used, then access the Shim data program and enter the quantity of shims added to each of the 24 mounting locations.

The pre-alignment of the level and aligned set of multiple CPV cells installed into each stamped module template, which are then installed into a paddle structure at the manufacturing facility minimize installation time in the field and improve the aggregate alignment of all of the CPV cells with respect to each other in the module.

The paddle assembly with the modules installed is shipped to the field to be installed. Next, the two paddles (forming a paddle pair) on each tracker stanchion are aligned with each in the field and installed on the two axis tracking mechanism. The paddle assembly, and this configuration and organization of the paddle assembly maintains the three dimensional alignment of the installed CPV cells during shipment as well as during an operation of the two axis tracker mechanism. The paddle structure supports the CPV modules and has a limited number of components to assemble in the field and in addition it is designed for easy installation.

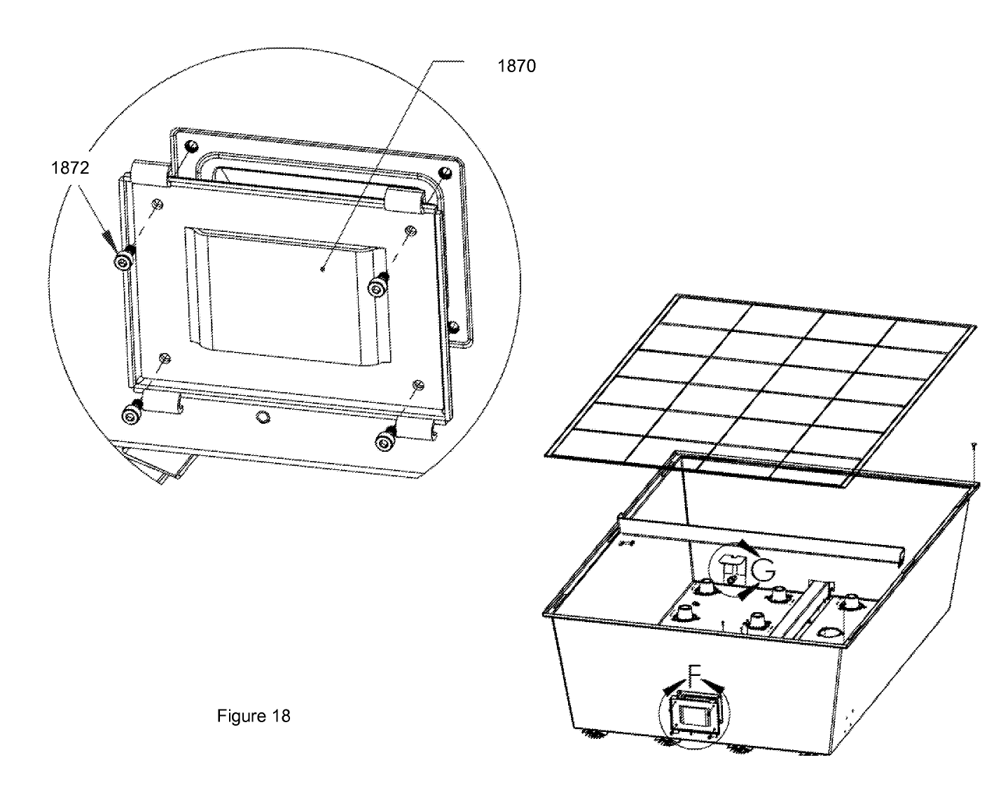

FIG. 18 illustrates a diagram of an embodiment of a module assembly created with a vent cover on the exterior of the module. FIG. 11 illustrates a diagram of an embodiment of a module assembly created with a recessed cavity in the wall of the module for the vent. The casing of the module has a recessed cavity in a wall of the module to house the vent filter, a cover over the membrane filter in the vent, and the casing of the module assembly must result in a water and dust leak-tight module to ensure module performance meets customer expectations for longevity in the field.

Next, beyond the receiver assembly, the improved casing of the module has a cavity to house the vent filter. The walls of the module have a pocket cavity to place the vent to prevent physical damage to the vent, and solar embrittlement from the concentrated solar radiation inside the module from affecting the vent. A metal cover can protect the vent inside the cavity. The vent maintains pressure within the module to be roughly the same as atmospheric pressure while restricting moisture and physical debris from entering inside the module cavity. This vent is located in the same geographical location on its module, so the vent for each of the modules can be serviceable on all modules in that row on the paddle. A filter membrane may be put into a vent flange. A cover screws and is torqued onto the vent plate assemblies into position over the vent holes on opposing sides of the chassis.

Referring to FIG. 15, each paddle structure has a bow shaped skeletal frame having a central tube for sliding the paddle structure onto the tilt axle, and multiple tab brackets for mechanically securing the modules in place. This overall structure of the paddle structure maintains a three dimensional alignment of the installed and aligned CPV solar cells in the one or more modules during shipment as well as during an operation of the two-axis tracker mechanism. The central support tube of the paddle slides onto the tilt axle of the two axis tracking mechanism. The solar array support structure may have couplings for easy installation of the paddle; and correspondingly, the paddle's design itself is configured for easy installation sliding of the paddle onto the tilt axle of the support structure mounted in concrete post. The manufactured and assembled paddle with modules assembly when arriving on the solar generation site consists of small number of unique components, such as 8, which results in a fewer number of steps/operations to install the arrays and paddle. Overall, the components including the Inner Bearing, the paddle with the CPV modules installed, the Outer Bearing, the Retainer Plate, and the 4 locking screws slide onto the Tilt Axle. The lead-in features help to align parts and prevent damage. The bearings do not engage until the paddle structure is fully into position. Note, the cylindrical center support tube of the paddle is made of a thin walled diameter material compared to the cylindrical tilt axis arm. Most of the torque of moving the paddle during operation will occur on the tilt axle rather than on the central support tube which is designed for coupling to the tilt axle. The paddle structure maintains the alignment of the installed modules during shipment and during the operation of the solar arrays. Additionally, breaking the surface area of densely populated CPV cells in a pair of paddles allows for easier shipping and easier installation.

Each module is tested for performance at the factory. The modules are pre-assembled and pre-wired into 2-kW paddle structures that are easily attached to the two-axis tracker assembly in the field.

The two axis tracker assembly its solar array and integrated housing have been designed to minimize labor and other costs during installation, and to provide for easier operation and maintenance. For example, the CPV modules are preassembled and pre-wired at the factory and can be installed directly from the pallet in the form of a paddle structure to the tracker. The sections and components making up the common roll axle, the single electronics housing mountable on the tracker, and the components for each paddle pair assembly are manufactured in simple modular sections that assemble easily in the field and also maintain a rough alignment of the tracker assembly.

Although the foregoing embodiments have been described in some detail for purposes of clarity of understanding, the invention is not limited to the details provided. The Solar array may be organized into one or more paddle pairs. Functionality of circuit blocks may be implemented in hardware logic, active components including capacitors and inductors, resistors, and other similar electrical components. The two-axis tracker assembly may be a multiple axis tracker assembly in three or more axes. There are many alternative ways of implementing the invention. The disclosed embodiments are illustrative and not restrictive.

We claim:

1. A solar array having multiple discreet components, comprising:
a set of solar receivers that are aligned within and mechanically secured in place in each module contained in a paddle structure making up that solar array, where each solar receiver has its own secondary concentrator optic optically coupled to a photovoltaic cell;
where each paddle structure is constructed such that one or modules with their set of solar receivers are contained in the paddle structure maintain the set of solar receivers' alignment when installed in the paddle structure in the fabrication process and while installed in the field;
where the set of solar receivers are aligned in three dimensions with each other by the fabrication process, and individual parts making up a given solar receiver are 1) shaped, 2) sized, 3) keyed, 4) pinned and 5) any combination of these to fit together in only one way so that all of the solar receivers in the set maintain their alignment when installed in a given module; and
where each paddle structure has a skeleton frame that couples to the one or more modules, which each module contains its own set of solar receivers arranged in a grid like pattern that are aligned in the three dimensions with each other during the fabrication process when installed in that module, and a configuration and organization of the paddle structure maintains the alignment of the installed modules during shipment as well as during an operation of the solar array.

2. The solar array of claim 1, where the one or more modules contained in the paddle structure are aligned and are mechanically secured parallel to each other in the plane of at least the diagonal Z dimension as they are attached to tab brackets of the skeletal frame of the paddle structure on a leveling fixture, where the paddle structure with the one or more modules installed are shipped to the field to be installed on a two axis tracker mechanism, and where two or more paddle structures form a paddle pair assembly on each tilt axle of the two axis tracking mechanism.

3. The solar array of claim 1, where a jig tool stamps each module casing template with placement cavities for the set of receivers installed in the module, and the same jig tool stamps the same pattern into each module template to set a depth, vertical, and horizontal alignment of the set of receivers when installed in the module, and the set of receivers are installed in the module template with the use of a receiver-to-chassis-attachment fixture that assists in establishing the vertical, horizontal, and diagonal alignment of the set of receivers in the module with respect to the other.

4. The solar array of claim 1, where each solar receiver has a casing with a lip that has indents in the shape of the lip that match a placement cavity stamped into a chassis of the module, and multiple holes in a base plate of each solar receiver are matched in shape and location to corresponding sets of holes in the chassis of the module.

5. The solar array of claim 4, where a first solar receiver in the set of solar receivers has rivets put into precisely drilled holes in the chassis of the module that exactly correspond to the holes in the base plate of the receiver, and where riveting mechanically secures an assembled and aligned solar receiver to the chassis of the module, and riveting allows for a tighter alignment of the solar receiver relative to known location in the chassis of the module than screws or nuts and bolts.

6. The solar array of claim 1, where a patterned panel of Fresnel lenses is assembled and aligned onto a top of a casing of the module that has placement pins at known fixed locations in a top lip of the module casing, and the patterned panel is properly placed relative to the casing of the module via the placement pins and a laser, where the patterned panel is organized into a grid of individual Fresnel lenses on that patterned panel that covers the set of receivers installed, and where the Fresnel lenses for all of the individual solar receivers installed into the module are manufactured from the same tool, and thus, each Fresnel lens in the grid of lenses for each of the individual solar receivers installed in the module template has a same optical characteristics.

7. The solar array of claim 1, where the modules loaded with the set of solar receivers mechanically secure to a frame of the paddle structure via a dynamic leveling mechanism including 1) shims between a bracket of the frame of the paddle structure and a threaded insert in a chassis of the module, 2) a threaded stud and one or more nuts between the bracket of the frame of the paddle structure and the threaded insert in the module, and 3) any combination of both, where the dynamic leveling mechanism is used to set and then maintain an alignment of a given solar receiver with respect to any other solar receiver in that paddle structure.

8. The solar array of claim 1, where the skeletal frame of the paddle structure has multiple tab brackets that are aligned to corresponding threaded holes in the modules to create multiple connection points per module to set and secure an alignment of the modules in the frame of the paddle.

9. The solar array of claim 1, where each paddle structure has a bow shaped skeletal frame having a central tube for sliding the paddle structure onto a tilt axle of a solar tracker assembly, and multiple brackets for mechanically securing the modules in place, where this overall structure of the paddle structure maintains a three dimensional alignment of the installed and aligned set of solar receivers within each of the modules during shipment as well as during an operation of the two-axis tracker mechanism.

10. The solar array of claim 1, where a first solar receiver has a secondary concentrator optically coupled to a multiple junction photovoltaic cell, where the secondary concentrator has a domed shaped top portion and a trapezoidal shaped bottom portion with walls, and the domed shaped secondary concentrator reflects a concentrated beam of light to within the walls of the trapezoidal shaped portion of the prism and onto the multiple junction photovoltaic cell, and the domed shaped top portion and trapezoidal bottom portion provide a larger acceptance angle than the trapezoidal bottom portion by itself, while also providing good homogenization of the light intensity across the surface of the multiple junction PV cell, and the domed shaped top portion and trapezoidal bottom portion merely fit centered within a casing of the solar receiver in one way.

11. The solar array of claim 1, where a first module has a casing with a recessed cavity in an internal wall of the module to house a vent filter, a cover for the vent filter, and the casing of the first module is configured to be water and dust leak-tight for longevity in the field.

12. The solar array of claim 1, where a first module has all of the solar receivers wired together internally within the first module, and a connection of the electrical wiring of the set of receivers inside of a module housing occurred while in the fabrication facility, and the module's inter-receiver wiring connection approach, connects the set of solar receivers electrically in parallel, electrically in series, electrically in series-parallel, and any combination of these, and merely the plus and minus DC output voltage leads from the set of the receivers within the module are externally exposed outside a housing of the module.

13. A method of creating a paddle structure with one or more sets of solar receivers that are aligned within and mechanically secured in place in each module contained in the paddle structure; comprising:
assembling and aligning a first solar receiver of a first set of solar receivers, where the assembly of the first solar receiver establishes the alignment of a secondary optic to a photovoltaic solar cell contained within the first solar receiver; and
where the first set of solar receivers is contained in an individual module and are aligned in three dimensions with each other by the fabrication process of a module template and subsequent installation of the first set of solar receivers into the module template, and where individual parts making up each solar receiver are 1) shaped, 2) sized, 3) keyed, 4) pinned and 5) any combination of these to fit together in only one way so that all of the solar receivers maintain their alignment when installed in a given CPV module.

14. An article of manufacture produced by the process of method claim 13.

15. The method of claim 13, further comprising:
assembling and aligning two or more modules, each containing a set of solar receivers, to a frame of the paddle structure using a combination of channels formed in the frame and brackets on the frame for positioning of the two or more modules.

16. The method of claim 13, further comprising:
assembling and aligning a set of solar receivers to a chassis of the module including riveting each of the receivers in the set of solar receivers with the chassis of the module, where the riveting occurs at multiple holes in a base plate of each of the receivers that are matched in shape and location to corresponding sets of holes in the chassis.

17. The method of claim 13, further comprising:
connecting electrical wiring of the set of solar receivers inside of a housing of the module while in the fabrication facility to eliminate wiring and testing the connections in the field, where a first module has all of the solar receivers electrically wired together internally within the module.

18. The method of claim 13, further comprising:
assembling and aligning a patterned panel of Fresnel lenses onto a top of a casing of the module that has placement pins at known fixed locations in a lip of the module casing, and using the placement pins and a laser to properly place the patterned panel relative to the lip of the module, where the patterned panel is organized into a grid of individual Fresnel lenses on that patterned panel that covers the set of receivers installed in the module.

19. The method of claim 13, further comprising:
mechanically securing one or more modules loaded with it own set of solar receivers to the frame of the paddle structure via a dynamic leveling mechanism including 1) shims between a tab bracket of the frame of the paddle structure and a threaded insert in a chassis of the module, 2) a threaded stud and one or more nuts between the bracket of the frame of the paddle structure and the threaded insert in the module, and 3) any combination of both, where the dynamic leveling mechanism is used to set and then maintain an alignment of a given solar receiver with respect to any other solar receiver in that paddle structure,

20. The method of claim 13, further comprising:
shipping the paddle structure with the modules installed to a site where a two axis tracker assembly is to be installed;
forming a paddle pair assembly on each tilt axle; and
setting the alignment of the paddle pair assembly on the two axis tracker assembly, which sets the alignment of all of the sets of solar receivers contained in the paddle pair assembly at the same time.
